(19) United States
(12) Patent Application Publication
(10) Pub. No.: US 2012/0224332 A1
(43) Pub. Date: Sep. 6, 2012

(54) INTEGRATED CIRCUIT PACKAGING SYSTEM WITH BUMP BONDED DIES AND METHOD OF MANUFACTURE THEREOF

(76) Inventors: JaEun Yun, Ichon (KR); Jong Wook Ju, Icheon-Si (KR)

(21) Appl. No.: 13/039,309

(22) Filed: Mar. 2, 2011

(51) Int. Cl. H05K 7/00; H05K 3/30; H05K 3/32

(52) U.S. Cl. 361/729; 29/832; 29/841

(57) ABSTRACT

An integrated circuit packaging system and method of manufacture thereof includes: a substrate; a first module attached to the substrate; a conductive connection built on the first module and conductively connected thereto; an adhesive spacer on the first module with the conductive connection exposed; and a second module on the adhesive spacer in conductive contact with the conductive connection and partially supported thereby.

### TECHNICAL FIELD

The present invention relates generally to an integrated circuit packaging system, and more particularly to a system for bump bonded dies.

### BACKGROUND ART

Products must compete in world markets and attract many consumers or buyers in order to be successful. It is very important for products to continue to improve in features, performance, and reliability while reducing product costs, product size, and equally important to be available quickly for purchase by the consumers or buyers.

The demand for high density and high output/input integrated circuit packages dramatically increased with the trend of electronic products toward lightweight, small size, multi-function, and high speed. Therefore, components in the package are becoming thinner and thinner to reduce the size of the whole package effectively. Electronic products such as cell phone base products, global positioning systems (GPS), satellites, communication equipment, consumer products, and a vast line of other similar products are in ever increasing global demand.

A small product, such as a cell phone, can contain many integrated circuit packages, each having different sizes and shapes. Each of the integrated circuit packages within the cell phone can contain large amounts of complex circuitry. The circuitry within each of the integrated circuit packages work and communicate with other circuitry of other integrated circuit packages and electrical parts using electrical connections on circuit boards.

Time to market, reliability, the number of integrated circuit packages, and the number of electrical parts on the circuit boards inside a product are important to improving the features, performance, and reliability of any product. Furthermore, the ways the circuitry and electrical connections are implemented have a direct impact on the availability, reliability, and costs of products.

Attempts have failed to provide a complete solution addressing simplified manufacturing processing, time to market, improved reliability, reduced electrical parts on the circuit boards, and size reductions of the circuit boards with increased functionality, leveragability, and increased product features to the consumer.

In particular, with bump bonded dies, where two dies are bonded using wire bumps to space apart the two dies, there have been numerous problems. For example, there would often be wire damage during the placement of the second die and also during bonding of the second die to the wire bonds of the first die. Also, other problems would occur during placement of the second die, the second die being damaged due to bending.

Further, for bump bonded dies having underfill or encapsulant molding compound between the first and second dies, problems would be encountered with the top die being damaged by tilting or bending, or the die becoming separated from the wire bonds during the injection underfill or molding process. The die displacement and separation from the wire bonds during the injection process occurs because of low adhesion between the wire bump and the individual die.

Thus, a process is required that needs no additional steps, can provide high units per hour production, and can provide a high quality and stable process.

In view of the problems and process requirements, it is increasingly critical that answers be found. In view of the ever-increasing commercial competitive pressures, along with growing consumer expectations and the diminishing opportunities for meaningful product differentiation in the marketplace, it is critical that answers be found for these problems. Additionally, the need to reduce costs, improve efficiencies and performance, and meet competitive pressures adds an even greater urgency to the critical necessity for finding answers to these problems.

Solutions to these problems have been long sought but prior developments have not taught or suggested any solutions and, thus, solutions to these problems have long eluded those skilled in the art.

### DISCLOSURE OF THE INVENTION

The present invention provides a method of manufacture of an integrated circuit packaging system including: attaching a first module to a substrate; building a conductive connection on the first module and conductively connected thereto; placing an adhesive spacer on the first module with the conductive connection exposed; and placing a second module on the adhesive spacer in conductive contact with the conductive connection and partially supported thereby.

The present invention provides an integrated circuit packaging system and method of manufacture thereof includes: a substrate; a first module attached to the substrate; a conductive connection built on the first module and conductively connected thereto; an adhesive spacer on the first module with the conductive connection exposed; and a second module on the adhesive spacer in conductive contact with the conductive connection and partially supported thereby.

Certain embodiments of the invention have other steps or elements in addition to or in place of those mentioned above. The steps or elements will become apparent to those skilled in the art from a reading of the following detailed description when taken with reference to the accompanying drawings.

### BRIEF DESCRIPTION OF THE DRAWINGS

FIG. 1 is a cross-sectional view in an initial stage of manufacture of a rectangular integrated circuit packaging system in an embodiment of the present invention.

FIG. 2 is the cross-sectional view of FIG. 1 in a further step of manufacture in the two different embodiments of the present invention.

FIG. 3 is the cross-sectional view of FIG. 2 in further steps of manufacturing in the two different embodiments of the present invention.

FIG. 4 is the cross-sectional view of FIG. 3 in a still further step of manufacture of the two different embodiments of the present invention.

FIG. 5 is a flow chart of a method of manufacturing of an integrated circuit packaging system in an embodiment of the present invention.

### BEST MODE FOR CARRYING OUT THE INVENTION

The following embodiments are described in sufficient detail to enable those skilled in the art to make and use the invention. It is to be understood that other embodiments would be evident based on the present disclosure, and that system, process, or mechanical changes may be made without departing from the scope of the present invention.

In the following description, numerous specific details are given to provide a thorough understanding of the invention. However, it will be apparent that the invention may be practiced without these specific details. In order to avoid obscuring the present invention, some well-known circuits, system configurations, and process steps are not disclosed in detail.

The drawings showing embodiments of the system are semi-diagrammatic and not to scale and, particularly, some of the dimensions are for the clarity of presentation and are shown exaggerated in the drawing FIGs. Similarly, although the views in the drawings for ease of description generally show similar orientations, this depiction in the FIGs. is arbitrary for the most part. Generally, the invention can be operated in any orientation.

Where multiple embodiments are disclosed and described having some features in common, for clarity and ease of illustration, description, and comprehension thereof, similar and like features one to another will ordinarily be described with similar reference numerals. The embodiments have been numbered first embodiment, second embodiment, etc. as a matter of descriptive convenience and are not intended to have any other significance or provide limitations for the present invention.

For expository purposes, the term “horizontal” as used herein is defined as a plane parallel to the plane or surface of the substrate, regardless of its orientation. The term “vertical” refers to a direction perpendicular to the horizontal as just defined. Terms, such as “above”, “below”, “bottom”, “top”, “side” (as in “sidewall”), “higher”, “lower”, “upper”, “over”, and “under”, are defined with respect to the horizontal plane, as shown in the figures. The term “on” means that there is direct contact between elements.

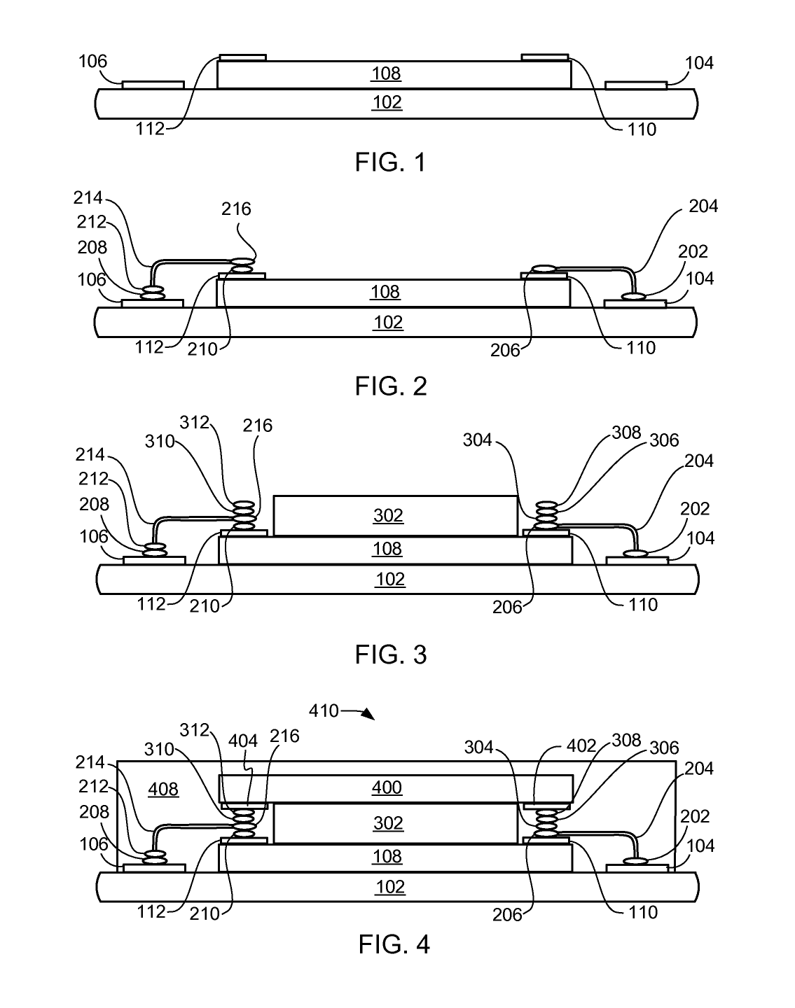

Referring now to FIG. 1, therein is shown a cross-sectional view in an initial stage of manufacture of a rectangular integrated circuit packaging system in an embodiment of the present invention.

A substrate 102 has bond pads 104 and 106. The substrate 102 may be a die, package, wiring, printed circuit board, or similar substrate.

A module 108 has bond pads 110 and 112. The module 108 can be an integrated circuit chip having an active surface or a package having a wiring substrate upon which the bond pads 110 and 112 are placed in conductive contact with integrated circuits in the module 108.

Referring now to FIG. 2, therein is shown the cross-sectional view of FIG. 1 in a further step of manufacture in two different embodiments of the present invention.

In one embodiment, a wire bond 202 formed on the bond pad 104 of the substrate 102 is conductively connected by a bond wire 204 to a wire bond 206 formed on the bond pad 110 on the module 108.

In another embodiment, a bump 208 is formed on the bond pad 106 of the substrate 102 and a bump 210 is formed on the bond pad 112 on the module 108. The bumps 208 and 210 may be solder bumps of a type used to join dissimilar metals. A wire bond 212 formed on the bump 208 is conductively connected by a bond wire 214 to a wire bond 216 formed on the bump 210.

Referring now to FIG. 3, therein is shown the cross-sectional view of FIG. 2 in further steps of manufacturing in the two different embodiments of the present invention.

An adhesive spacer 302 is bonded on the module 108 between the bond pads 110 and 112. The adhesive spacer 302 has vertical edges with the characteristic cut marks of being cut in a cutting machine from a film of adhesive material or an adhesive-coated film.

In one embodiment, a bump 304 is bonded to the wire bond 206. The bump 304 by itself or with additional bumps, such as bumps 306 and 308, will be substantially the same vertical height as the height of the adhesive spacer 302. The bumps 304, 306, and 308 may be solder bumps of a type used to join dissimilar metals.

In another embodiment, a bump 310 will be bonded to the wire bond 216 and by itself, or with another bump 312 will be substantially the same vertical height as the height of the adhesive spacer 302. The bumps 310 and 312 may be solder bumps of a type used to join dissimilar metals.

Referring now to FIG. 4, therein is shown the cross-sectional view of FIG. 3 in a still further step of manufacture of the two different embodiments of the present invention.

A module 400 has bond pads 402 and 404. The module 400 can be an integrated circuit chip having an active surface or a package having a wiring substrate upon which the bond pads 402 and 404 placed in conductive contact with integrated circuits in the module 400.

In one embodiment the module 400 is adhesively bonded to the adhesive spacer 302 such that the bond pad 402 is in conductive contact and bonded to the top bump of the bump stack that includes the wire bond 206. Thus, the wire bond 206 and the bumps 304, 306, and 308 build a conductive connection among the bond pads 104, 110, and 402.

In another embodiment the module 400 is adhesively bonded to the adhesive spacer 302 such that the bond pad 404 is in conductive contact and bonded to the top bump of the bump stack that includes the wire bond 216. Thus, the wire bond 216 and the bumps 210, 310, and 312 build a conductive connection among the bond pads 106, 112, and 404.

The module 400 is jointly supported by the conductive connection of the wire bond 206 and the bumps 304, 306, and 308, the conductive connection of the wire bond 216 and the bumps 210, 310, and 312, and the adhesive spacer 302.

A package encapsulant 408, such as an underfill having a Coefficient of Thermal Expansion matching the solder bumps or package epoxy mold compound is injection molded to protect the module 108, the module 400, and all the conductive components to form an integrated circuit packaging system 410.

It has been discovered that the adhesive spacer 302 and the various wire bumps prevent wire damage during placement of the module 400 on the adhesive spacer 302.

It has been further discovered that the adhesive spacer 302 prevents bending of the module 400 during placement and bonding of the module 400 on the various bumps.

It has been further discovered that the adhesive spacer 302 takes up the space under the module 400 where underfill or epoxy molding compound would be able to cause tilt or bending of the module 400 and thus prevents the tilt or bending.

It has been further discovered that adhesive characteristics of the adhesive spacer 302 prevents underfill or epoxy molding compound from causing separation of the module 400 from the stack of bumps because of low adhesion between the module 302 and the bump 308 or 312 the during injection insertion of the underfill or epoxy molding compound.

It has been further discovered that adhesive characteristics of the adhesive spacer 302 prevents underfill or epoxy molding compound from causing tilting or bending of the module 400 during injection insertion of the underfill or epoxy molding compound.

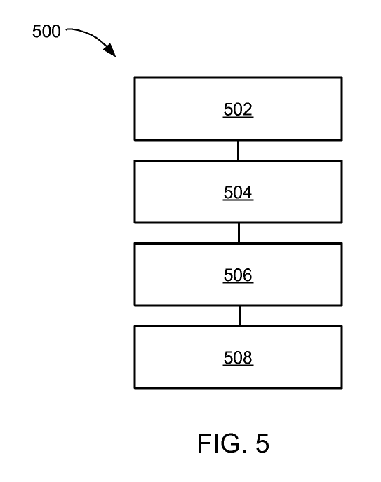

Referring now to FIG. 5, therein is shown a flow chart of a method of manufacturing of an integrated circuit packaging system in an embodiment of the present invention.

A manufacturing method 500 includes: attaching a first module to a substrate in a block 502; building a conductive connection on the first module and conductively connected thereto in a block 504; placing an adhesive spacer on the first module with the conductive connection exposed in a block 506, and placing a second module on the adhesive spacer in conductive contact with the conductive connection and partially supported thereby in a block 508.

The resulting method, process, apparatus, device, product, and system are straightforward, cost-effective, uncomplicated, highly versatile and effective, can be surprisingly and unobviously implemented by adapting known technologies, and are thus readily suited for efficiently and economically manufacturing packaging systems and are fully compatible with conventional manufacturing methods or processes and technologies.

Another important aspect of the present invention is that it valuably supports and services the historical trend of reducing costs, simplifying systems, and increasing performance.

These and other valuable aspects of the present invention consequently further the state of the technology to at least the next level.

While the invention has been described in conjunction with a specific best mode, it is to be understood that many alternatives, modifications, and variations will be apparent to those skilled in the art in light of the aforegoing description. Accordingly, it is intended to embrace all such alternatives, modifications, and variations that fall within the scope of the included claims. All matters hithertofore set forth herein or shown in the accompanying drawings are to be interpreted in an illustrative and non-limiting sense.

What is claimed is:

1. A method of manufacture of an integrated circuit packaging system comprising:
attaching a first module to a substrate;
building a conductive connection on the first module and conductively connected thereto;
placing an adhesive spacer on the first module with the conductive connection exposed; and
placing a second module on the adhesive spacer in conductive contact with the conductive connection and partially supported thereby.

2. The method as claimed in claim 1 wherein building the conductive connection conductively connects the first module to the substrate.

3. The method as claimed in claim 1 wherein building the conductive connection conductively connects the conductive connection to the substrate closer to the first module than to the second module.

4. The method as claimed in claim 1 further comprising cutting the adhesive spacer from a film.

5. The method as claimed in claim 1 further comprising encapsulating the first and second modules and the conductive connection.

6. A method of manufacture of an integrated circuit packaging system comprising:
attaching a first module to a substrate, the first module and the substrate each having bond pads;
building conductive connections of bumps and bonds on the bond pads of the first module and conductively connected thereto;
placing an adhesive spacer on the first module between two of the bond pads with the conductive connections exposed; and
placing a second module on the adhesive spacer in conductive contact with the conductive connections and partially supported thereby.

7. The method as claimed in claim 6 wherein building the conductive connection includes a bond wire conductively connecting the first module and the second module to the substrate.

8. The method as claimed in claim 6 wherein building the conductive connection includes a bond wire conductively connecting the conductive connection to the substrate closer to the first module than to the second module.

9. The method as claimed in claim 6 further comprising cutting the adhesive spacer from an adhesive material or adhesive-coated film.

10. The method as claimed in claim 6 further comprising encapsulating the first and second modules, the conductive connections, and the bond pads.

11. An integrated circuit packaging system comprising:
a substrate;
a first module attached to the substrate;
a conductive connection built on the first module and conductively connected thereto;
an adhesive spacer on the first module with the conductive connection exposed; and
a second module on the adhesive spacer in conductive contact with the conductive connection and partially supported thereby.

12. The system as claimed in claim 11 wherein the conductive connection conductively connects the first module to the substrate.

13. The system as claimed in claim 11 wherein the conductive connection conductively connects the conductive connection to the substrate closer to the first module than to the second module.

14. The system as claimed in claim 11 further comprising the adhesive spacer having characteristics of being cut from a film.

15. The system as claimed in claim 11 further comprising an encapsulation encapsulating the first and second modules and the conductive connection.

16. The system as claimed in claim 11 wherein:
the first module and the substrate each have bond pads;
the conductive connections are built of bumps and bonds on the bond pads of the first module and are conductively connected thereto; and
the adhesive spacer is on the first module between two of the bond pads with the conductive connections exposed.

17. The system as claimed in claim 16 wherein the conductive connection includes a bond wire conductively connecting the first module and the second module to the substrate.

18. The system as claimed in claim 16 wherein the conductive connection includes a bond wire conductively connecting the conductive connection to the substrate closer to the first module than to the second module.

19. The system as claimed in claim 16 further comprising the adhesive spacer has characteristics of being cut from an adhesive material or adhesive-coated film.

20. The system as claimed in claim 16 further comprising an encapsulant encapsulating the first and second modules, the conductive connections, and the bond pads.
